(19) United States
(12) Patent Application Publication
(10) Pub. No.: US 2015/0030766 A1
(43) Pub. Date: Jan. 29, 2015

(54) PEDESTAL BOTTOM CLEAN FOR IMPROVED FLUORINE UTILIZATION AND INTEGRATED SYMMETRIC FORELINE

(71) Applicant: Novellus Systems, Inc., Fremont, CA (US)

(72) Inventors: Gary B. Lind, Nevada City, CA (US); Abhishek A. Manohar, San Jose, CA (US); Yan Guan, Cupertino, CA (US); Raashina Humayun, Los Altos, CA (US)

(21) Appl. No.: 13/950,991

(22) Filed: Jul. 25, 2013

(51) Int. Cl. C23C 16/44; H01L 21/02

(52) U.S. Cl. CPC C23C 16/4405; H01L 21/02068; C23C 16/4412
USPC 427/209; 118/728; 134/22.1; 137/561 A; 427/248.1; 427/250

(57) ABSTRACT

A technique and apparatus for cleaning the underside of a pedestal in a single- or multi-station semiconductor processing chamber or tool are provided. Also provided is an integrated vacuum foreline manifold having symmetric flow path lengths that may be used in multi-station semiconductor processing chamber or tool.

### BACKGROUND

In some semiconductor processing operations, e.g., deposition operations, material may be deposited on a semiconductor wafer or other substrate housed within a semiconductor processing chamber by flowing gas across the semiconductor wafer or substrate using a showerhead. Such material may also, to varying extents, be deposited on other surfaces within the semiconductor processing chamber as the flowed deposition gas flows off of the wafer and contacts other surfaces of the semiconductor processing chamber. Over time, the deposited layers may accumulate on various surfaces of the semiconductor processing chamber to such an extent that the accumulation may affect process performance. When such an accumulation is reached, a cleaning process may be performed to remove the accumulated material.

Such cleaning processes often resemble etching processes and may involve flowing activated fluorine gas or other etch-type gas into the semiconductor processing chamber via the showerhead. The cleaning gas may be flowed until the accumulated deposition material is removed to a satisfactory degree.

### SUMMARY

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale unless specifically indicated as being scaled drawings.

In some implementations, a method is provided for cleaning a semiconductor processing chamber containing a showerhead, a pedestal with a wafer support side facing the showerhead and an underside opposite the wafer support side, and one or more auxiliary cleaning gas ports configured to flow cleaning gas towards the underside of the showerhead. The method may include flowing a first cleaning gas from the showerhead towards the wafer support side of the pedestal and flowing a second cleaning gas from the one or more auxiliary cleaning gas ports towards the underside of the pedestal.

In some implementations of the method, the first cleaning gas and the second cleaning gas may be the same gas.

In some implementations of the method, the second cleaning gas may be activated fluorine.

In some implementations of the method, the first cleaning gas and the second cleaning gas may be flowed for substantially coextensive periods of time.

In some implementations of the method the one or more auxiliary cleaning gas ports may include a plurality of auxiliary cleaning gas ports arranged in a substantially circular pattern centered on the pedestal. In some such implementations of the method, the semiconductor processing chamber may further include a plurality of vacuum ports arranged in a substantially circular pattern centered on the pedestal and located within the substantially circular pattern that the plurality of auxiliary cleaning gas ports is in. In such implementations, the method may further include drawing a vacuum through the vacuum ports to cause the second cleaning gas to flow into the vacuum ports.

In some such implementations, the pedestal may have a nominal outer diameter and the substantially circular pattern of vacuum ports may have a diameter less than the nominal outer diameter and the substantially circular pattern that the plurality of auxiliary cleaning gas ports are in may have a diameter greater than the nominal outer diameter.

In some implementations of the method, the method may further include flowing deposition gas from the showerhead towards the wafer support side of the pedestal and drawing a vacuum through the vacuum ports to cause the deposition gas to flow into the vacuum ports.

In some such implementations of the method, the method may further include accumulating a deposition layer on the support side of the pedestal and on the underside of the pedestal. The deposition layer may have a first average thickness on the support side of the pedestal and a second average thickness on the underside of the pedestal. The second average thickness may be greater than the first average thickness.

In some such implementations of the method, the deposition gas may be a tungsten deposition gas.

In some implementations of the method, the first cleaning gas may remove the deposition layer on the support side of the pedestal with a greater efficiency than the first cleaning gas removes the deposition layer on the underside of the pedestal, and the second cleaning gas may remove the deposition layer on the underside of the pedestal with a greater efficiency than the second cleaning gas removes the deposition layer on the support side of the pedestal.

In some implementations, a semiconductor processing chamber may be provided. The semiconductor processing chamber may include a chamber housing; a pedestal having a wafer support side and an underside opposite the wafer support side, the pedestal located within the chamber housing; and a plurality of auxiliary cleaning gas ports located within the chamber housing and such that the underside of the pedestal is between the wafer support side of the pedestal and the plurality of auxiliary cleaning gas ports, the auxiliary cleaning gas ports oriented to flow an auxiliary gas onto the underside of the pedestal.

In some implementations, the semiconductor processing chamber may also include a showerhead located such that the wafer support side of the pedestal is between the underside of the pedestal and the showerhead. The showerhead may be configured to flow deposition gas onto the pedestal. In some such implementations, the showerhead may be further configured to flow a cleaning gas onto the showerhead.

In some implementations, a plurality of vacuum ports may be located within the chamber housing and such that the underside of the pedestal is between the wafer support side of the pedestal and the plurality of vacuum ports.

In some implementations, the auxiliary cleaning gas ports of the plurality of auxiliary cleaning gas ports may be arranged in a substantially circular pattern about a center axis of the pedestal, and the vacuum ports of the plurality of vacuum ports may be arranged in a substantially circular pattern about the center axis of the pedestal. In some such implementations, the substantially circular pattern of auxiliary cleaning gas ports may have a larger nominal pattern diameter than the substantially circular pattern of vacuum ports.

In some implementations, a vacuum foreline manifold may be provided. The vacuum foreline manifold may include a manifold body, two U-shaped passages within the manifold body, a bridging passage within the manifold body, and a feed passage. Each U-shaped passage may have two manifold vacuum ports passing out of the manifold body, and each of the two manifold vacuum ports may be located at a different end of the U-shaped passage. The bridging passage may have a first end and a second end. The first end of the bridging passage may be fluidly connected with one of the U-shaped passages at the U-shaped passage's midpoint, and the second end of the bridging passage may be fluidly connected with the other U-shaped passage at the other U-shaped passage's midpoint. The feed passage may be fluidly connected to the bridging passage at the bridging passage's midpoint and the feed passage, the bridging passage, and the U-shaped passages may all follow two-dimensional paths in the same plane or parallel planes.

In some implementations, the manifold body may have a substantially flat first side and the manifold vacuum ports may all exit the manifold body on the first side.

In some implementations, the feed passage may have a cross-sectional flow area Y, the bridging passage may have a cross-sectional flow area of approximately 0.75Y, and the U-shaped passages may both have a cross-sectional flow area of approximately 0.5Y.

In some implementations, the feed passage, the bridging passage, and the U-shaped passages may all have substantially the same height in a direction perpendicular to the plane or planes of the two-dimensional paths.

In some implementations, the manifold body may have a height in a direction perpendicular to the plane or planes of the two-dimensional paths that is between about 10% and 30% greater than a maximum height in a direction perpendicular to the plane or planes of the two-dimensional paths of the feed passage, the bridging passage, and the U-shaped passages.

In some implementations, an apparatus may be provided. The apparatus may include a process chamber and at least two pedestal assemblies located within the process chamber. Each pedestal assembly may be associated with a different process station within the process chamber, may have a pedestal with a wafer support side and an underside opposite the wafer support side, and may have a center axis substantially centered on the pedestal and normal to the wafer support side. The apparatus may also include two or more sets of vacuum ports, each set of vacuum ports associated with a different one of the at least two pedestal assemblies and located in a surface or surfaces within the process chamber that face the underside of the associated pedestal assembly. The apparatus may also include a vacuum foreline manifold, the vacuum foreline manifold positioned such that the vacuum ports are interposed between the vacuum foreline manifold and the undersides of the pedestal assemblies. In turn, the vacuum foreline manifold may include a manifold body, two U-shaped passages within the manifold body, a bridging passage within the manifold body, and a feed passage. Each U-shaped passage may have two manifold vacuum ports passing out of the manifold body, and each of the two manifold vacuum ports may be located at a different end of the U-shaped passage. The bridging passage may have a first end and a second end. The first end of the bridging passage may be fluidly connected with one of the U-shaped passages at the U-shaped passage's midpoint, and the second end of the bridging passage may be fluidly connected with the other U-shaped passage at the other U-shaped passage's midpoint. The feed passage may be fluidly connected to the bridging passage at the bridging passage's midpoint and the feed passage, the bridging passage, and the U-shaped passages may all follow two-dimensional paths in the same plane or parallel planes.

In some such implementations, the at least two pedestal assemblies may include four pedestal assemblies, the two or more sets of vacuum ports may include four sets of vacuum ports, the apparatus may further include an additional vacuum foreline manifold that is substantially a mirror image of the vacuum foreline manifold, and the feed passages of the vacuum foreline manifold and the additional vacuum foreline manifold may both have feed vacuum ports that connect to a common vacuum source.

These and other aspects of this disclosure are explained in more detail with reference to the accompanying Figures listed below.

### BRIEF DESCRIPTION OF THE DRAWINGS

FIG. 1 depicts a schematic of an example of a semiconductor processing chamber configured for cleaning a pedestal bottom.

FIG. 2 depicts a high-level flow diagram of a technique for cleaning the underside of a pedestal in a semiconductor processing chamber.

FIG. 3A depicts an isometric view of a portion of an example of a multi-station semiconductor processing tool.

FIG. 3B depicts an isometric exploded view of the example multi-station semiconductor processing tool of FIG. 3A.

FIG. 3C depicts an isometric detail view of a portion of the example multi-station semiconductor processing tool of FIG. 3A contained within the dotted rectangle.

FIG. 3D depicts an isometric view of an example vacuum foreline manifold included in the example multi-station semiconductor processing tool of FIG. 3A.

FIG. 3D′ depicts a removed broken section view of a portion of the example vacuum foreline manifold of FIG. 3D.

FIG. 3E depicts an isometric top section view of the example vacuum foreline manifold shown in FIG. 3D.

FIG. 3F depicts a bottom section view of the example vacuum foreline manifold shown in FIG. 3D.

FIGS. 3G and 3G′ depict a bottom isometric view of a multi-station semiconductor processing tool having a traditional vacuum foreline and an exploded view of the traditional vacuum foreline, respectively.

FIG. 3H depicts a top view of the example multi-station semiconductor processing tool of FIG. 3A with some components removed.

FIG. 3I depicts a top view of the example multi-station semiconductor processing tool of FIG. 3A with some additional components removed.

FIG. 3J depicts an off-angle cutaway view of the example multi-station semiconductor processing tool of FIG. 3A.

FIG. 3K depicts a detail view of the portion of the example multi-station semiconductor processing tool of FIG. 3J contained within the dotted rectangle.

FIGS. 3A through 3K are drawn to scale within each Figure, although not necessarily from Figure to Figure.

### DETAILED DESCRIPTION

Examples of various implementations are illustrated in the accompanying drawings and described further below. It will be understood that the discussion herein is not intended to limit the claims to the specific implementations described. On the contrary, it is intended to cover alternatives, modifications, and equivalents as may be included within the spirit and scope of this disclosure as defined by the appended claims. In the following description, numerous specific details are set forth in order to provide a thorough understanding of the present disclosure. The present disclosure may be practiced without some or all of these specific details. In other instances, well-known process operations have not been described in detail in order not to unnecessarily obscure the present disclosure.

Described herein are techniques, as well as equipment for performing such techniques, for cleaning accumulated deposition material off of the underside of a pedestal. Such techniques may be used in both single-chamber semiconductor processing chambers as well as in single or multi-chamber multi-station semiconductor processing tools. Also discussed herein is an integrated vacuum foreline that may be used in a multi-station semiconductor processing tool to, among other things, facilitate the pedestal underside cleaning techniques discussed herein. Applicants note that while the integrated vacuum foreline may be primarily of use in multi-station semiconductor processing tools, the pedestal underside cleaning technique and equipment discussed herein may be used on both multi-station semiconductor processing tools and on single-station, single-chamber semiconductor processing equipment.

It is to be understood that the use of relative terms such as “above,” “on top,” “below,” “underneath,” “underside,” etc. are to be understood to refer to spatial relationships of components with respect to the orientations of those components during normal use of a semiconductor processing chamber or tool, e.g., with a showerhead oriented so as to distribute gases downwards towards a wafer during wafer processing operations.

It is also to be understood that the term “substantially” may be used herein in a number of contexts. For example, many features described herein may be arranged in certain patterns, e.g., circular patterns, and the term “substantially” may be used to describe the overall shape of such patterns. There may nonetheless be some variation from a true circle in the placement of such features—a person of ordinary skill in the art would, however, still recognize such patterns as “circular.” Similarly, the term “substantially” may be used to describe one components positioning relative to another component or to a reference feature. For example, a component that is substantially centered on a center axis of another component may not be precisely centered on another component due to tolerance variations or minor asymmetries in a part. One of ordinary skill in the art, however, would recognize that such components are still substantially centered on such center axes. In another example, a “substantially annular” component or space may have an overall appearance that is annular, but, for example, a chord section may be removed from an outer surface of the annular component or space (producing a “flat” spot on the outer surface). Such components or spaces would still, however, be describable as “substantially symmetric.”

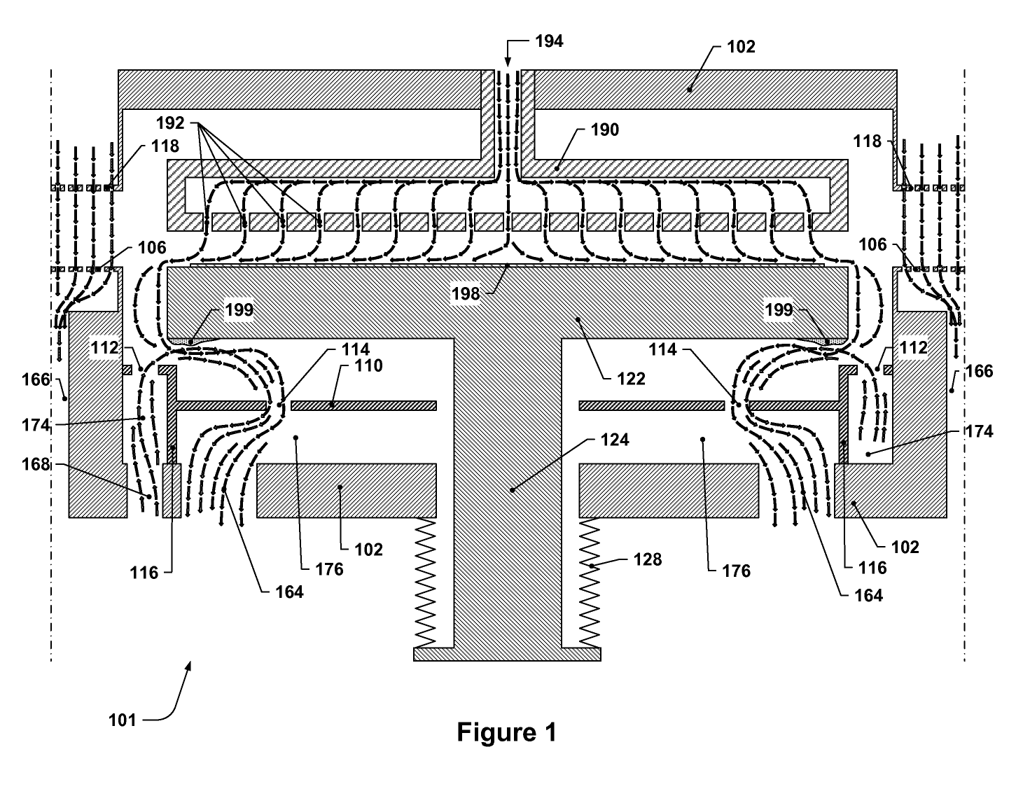

FIG. 1 depicts a schematic of an example of a semiconductor processing chamber configured for cleaning a pedestal bottom. A semiconductor processing chamber 101 is shown; the semiconductor processing chamber 101 may include a pedestal 122 (also commonly referred to as a wafer support) and a showerhead 190. The pedestal 122 may have a chuck or other mechanism for holding a semiconductor wafer 198 or other substrate on the pedestal during semiconductor processing. The pedestal 122 may, in many implementations, be generally circular in shape and have a nominal diameter that is larger than the semiconductor wafer 198 or substrate that it supports. The pedestal 122 may be supported on a pedestal support column 124 that may be driven by a linear actuator to allow the pedestal 122 to be moved vertically with respect to the chamber housing 102. A bellows 128 or other seal may be used to seal the translational interface between the pedestal support column 124 and the chamber housing 102.

The showerhead 190 may include an inlet 194 (or inlets) that provides process gases (black arrows) to a plenum that conveys the processes gases to a plurality of gas distribution holes 192. The gas distribution holes 192 may distribute the process gases across the semiconductor wafer 198. The process gases may, for example, be deposition process gases.

In many multi-station semiconductor processing tools, the chamber housing 102 (or a lid that mounts to the chamber housing) may include one or more curtain gas baffles 118 that may direct a gas “curtain,” e.g., argon, down towards interstitial baffles 106. The gas curtain (grey arrows) may assist in keeping process gases delivered from the showerhead 190 contained within the vicinity of the semiconductor wafer 198. The gas curtain (and attendant hardware) may be optional in single-station tools and may even be optional in various multi-station tools as well. The curtain gas may be drawn into the interstitial baffles 106 by a vacuum that is drawn via housing interstitial vacuum ports 166.

In order to assist with process gas removal, a substantially circular array of vacuum ports 114 may be substantially centered beneath the pedestal 122. The vacuum ports 114 may be located in a pedestal well baffle 110, and may communicate with a vacuum plenum volume 176 located between the pedestal well baffle 110 and the chamber housing 102. A plurality of housing vacuum ports 164 may be located about the vacuum plenum volume 176 in a substantially radially-symmetric manner.

During cleaning operations, a cleaning gas, e.g., activated fluorine or other suitable cleaning gas, may be flowed through the showerhead 190 and over the pedestal 122. Such showerhead-sourced cleaning gas flow is common in semiconductor operations and leverages hardware that is already present, e.g., the showerhead 190 that supplies deposition process gases to the semiconductor wafer 198, to flow the cleaning gas over the pedestal 122 and exposed equipment within the chamber housing 102. In some designs, cleaning gases may be flowed through the same gas flow paths in the showerhead 190 that are used to provide deposition gases (or vapors or liquids). In other designs, however, there may be a plenum and gas distribution holes separate from those used to deliver deposition gas and within the showerhead 190 that are used to deliver the cleaning gases.

The present inventors, however, have realized several shortcomings of such showerhead-centric cleaning techniques. For example, deposition material may accumulate on the underside of the pedestal 122, as shown by accumulated deposition material 199, as well as on other exposed surfaces of the pedestal 122, e.g., on the top and sides of the pedestal 122, and on other surfaces in the processing chamber (a lesser degree of deposition material may accumulate on the top surface of the pedestal 122 in the region or regions where a wafer sits during deposition processing, of course). Cleaning gases, e.g., activated species, may suffer depletion and recombination as such gases flow across the top and sides of the pedestal. This results in the cleaning efficacy of the cleaning gases decreasing as the cleaning gases flow across the pedestal 122, down the sides of the pedestal 122, and then across the underside of the pedestal 122. These factors may, for example, require that the cleaning gas be flowed through the showerhead 190 for nearly twice as long to clean the underside of the pedestal 122 as is required to clean the top of the pedestal. As a result, the top of the pedestal may be exposed to cleaning gas for longer durations than are necessary to actually clean the top of the pedestal. This may not only result in the desired removal of the accumulated deposition material on the pedestal 122 and other components and/or surfaces within the chamber housing 102, but may also result in undesired removal of material from (or etching of) the structures forming the pedestal 122 and other components. For example, exclusion rings, which are often placed on the top of the pedestal 122 and around the semiconductor wafer 198 and may be part of the pedestal assembly 120, may have thin features that are susceptible to damage, e.g., that may be “etched” away due to prolonged exposure to cleaning gases.

The present inventors have realized that a new processing chamber design may allow for a reduced-duration cleaning technique to be implemented. For example, the present inventors have realized that providing an auxiliary cleaning gas flow from a location beneath the pedestal 122 may allow for the auxiliary cleaning gas to be delivered to the underside of the pedestal 122 in a much more efficient manner, i.e., without suffering the depletion and recombination that may occur with cleaning gas that may be flowed from the showerhead 190.

For example, in FIG. 1, the pedestal well baffle 110 may include a substantially circular pattern of auxiliary cleaning gas ports 112 that may be fed by a cleaning gas plenum 174, e.g., a substantially annular plenum that is connected with a housing cleaning port (or ports) 168. In the implementation shown, the cleaning gas plenum 174 and the vacuum plenum 176 are separated by a partition wall 116 that is part of the pedestal well baffle 110, although other implementations may separate the two plenums using other structures. Auxiliary cleaning gas that is provided to the cleaning gas plenum 174 via the housing cleaning port 168 may flow throughout the cleaning gas plenum 174 and may then flow through the auxiliary cleaning gas ports 112 and towards the underside of the pedestal 122. After flowing across the underside of the pedestal 122, the auxiliary cleaning gas may be drawn into the vacuum ports 114 and evacuated from the chamber housing 102.

The showerhead 190 may have a large number of small features through which gas flows, e.g., the gas inlet 194, valve manifolds, fittings, the gas distribution holes 192, and other potential structures. The size of such features is often dictated by process uniformity concerns with respect to the wafers that are processed by the showerhead, i.e., such features are typically widely dispersed and of a small size so as to provide a distributed, uniform flow rate across the semiconductor wafer 198. Other features may further limit the size and distribution of such features, e.g., showerheads may have internal cooling passages in the showerhead faceplate that limit the size of the gas distribution holes.

As a result, the mean free path of cleaning gas molecules with respect to the physical structures of the showerhead 190, i.e., the average distance that a cleaning gas molecule travels before colliding with a surface or feature of the showerhead 190, may be relatively short, causing such cleaning gas molecules to collide with the structures or features of the showerhead 190 multiple times before reaching the surfaces that are to be cleaned. Each such collision may result in the cleaning gas molecule recombining with molecules in the structure or feature and thus becoming ineffective for cleaning purposes.

By contrast, the structures used to provide the auxiliary cleaning gas flow may not be subject to such constraints. According, the auxiliary cleaning gas flow may flow through features that are relatively large as compared with the features within the showerhead 190 and may consequently have a mean free path with respect to the physical structures through which the auxiliary cleaning gas flows that is larger than that of cleaning gas that flows through the showerhead 190. As a result, the auxiliary cleaning gas may suffer less collisions and thus have less opportunity to recombine prior to reaching the underside of the pedestal 122, i.e., the surface to be cleaned. Accordingly, the auxiliary cleaning gas may remove the accumulated deposition material 199 that is located on the underside of the pedestal 122 at a much higher rate, i.e., with greater efficiency, as compared with the cleaning gas that is flowed through the showerhead 190 (at least, for the same mass flow rate of cleaning gas).

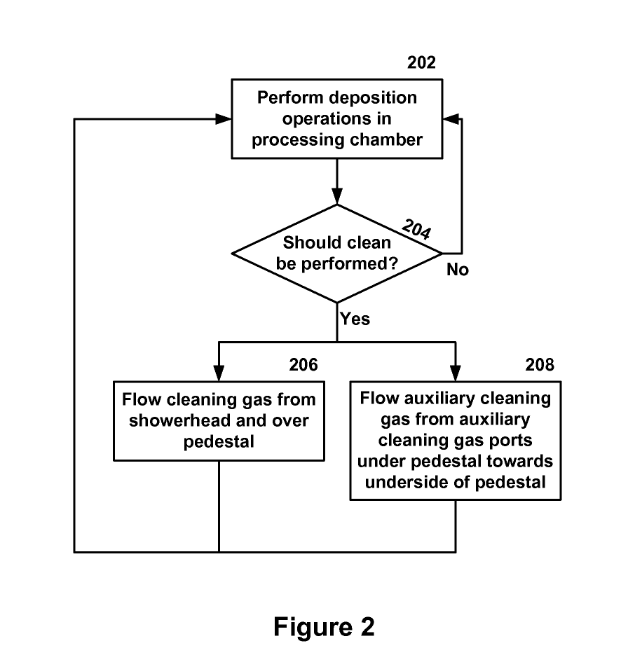

The underside cleaning technique discussed above may be described, at a high level, with reference to FIG. 2. FIG. 2 depicts a high-level flow diagram of a technique for cleaning the underside of a pedestal in a semiconductor processing chamber.

In block 202, deposition gas is flowed into the processing chamber to deposit material on a semiconductor wafer supported on a pedestal. The deposition gas may be flowed from a showerhead in the processing chamber in a substantially uniform manner across the semiconductor wafer. After sufficient material has been deposited on the semiconductor wafer, the semiconductor wafer may be removed from the chamber and a new semiconductor wafer may be placed in the chamber and further deposition gas may be flowed. Such deposition processes may be performed for a plurality of semiconductor wafers.

In block 204, an evaluation may be made as to whether a cleaning operation should be performed. The evaluation may occur during deposition processing, or may occur after each semiconductor wafer's deposition process completes. It may be necessary to remove the semiconductor wafer from the processing chamber prior to a cleaning operation to prevent damage to the semiconductor wafer. The evaluation may be based on an in-situ measurement, e.g., a measurement of the thickness of accumulated deposition material on certain reference surfaces within the processing chamber (such as the underside of the pedestal), or may be based on some other metric, e.g., the number of deposition operations performed. If no cleaning operation is warranted, the technique may return to block 202 and further deposition operations may be performed.

If block 204 results in a decision to perform a cleaning technique, however, the deposition gas may be stopped and cleaning gases may be flowed into the chamber in blocks 206 and 208. The semiconductor wafer, as discussed above, may be removed prior to the cleaning operation. In block 206, cleaning gas may be flowed from the showerhead towards the pedestal. The cleaning gas may be, for example, an activated species of fluorine.

In block 208, an auxiliary cleaning gas may be flowed from a substantially circular pattern of auxiliary cleaning gas ports in a surface located beneath the pedestal towards the underside of the pedestal, i.e., a side of the pedestal opposite the side of the pedestal that normally supports semiconductor wafers during deposition operations. Blocks 206 and 208 may be performed contemporaneously with one another. In some such implementations, the durations of blocks 206 and 208 may be the same, whereas in some other such implementations, the durations may be different, e.g., block 206 may be performed for a first duration and block 208 may be performed for a second, longer duration. The auxiliary cleaning gas of block 208 and the cleaning gas of block 206 may be the same type of cleaning gas or may be different types of cleaning gas. Even if the cleaning gas and the auxiliary cleaning gas (sometimes referred to herein as the “first cleaning gas” and the “second cleaning gas,” respectively) are the same type of gas, they may be supplied from different cleaning gas sources.

After blocks 206 and 208 are completed, the technique may return to block 202 for the performance of further deposition operations.

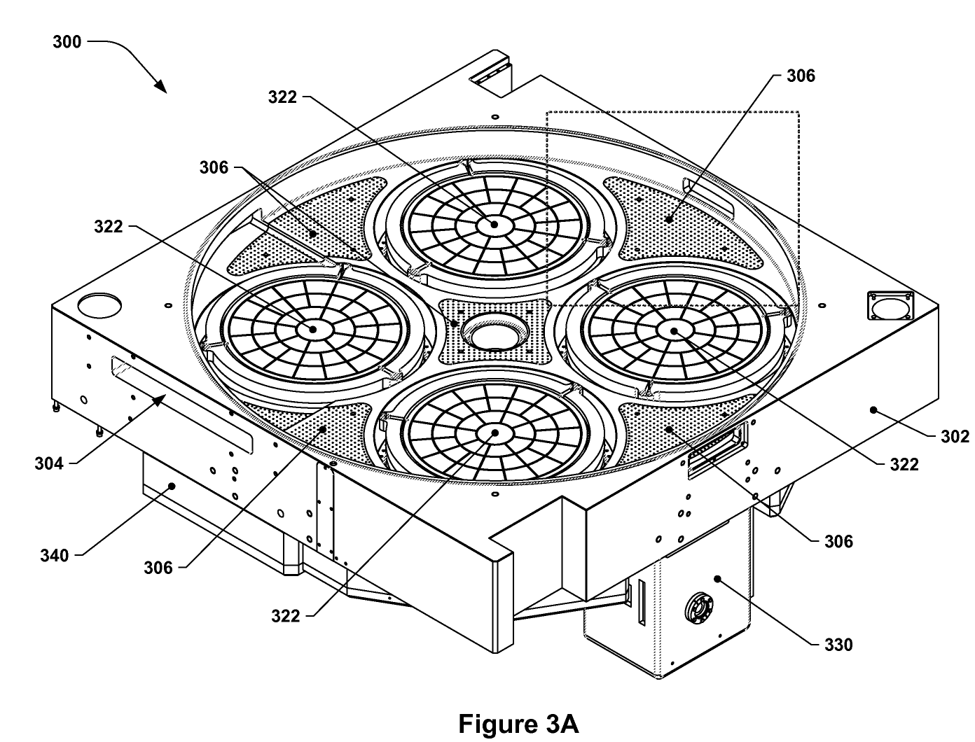

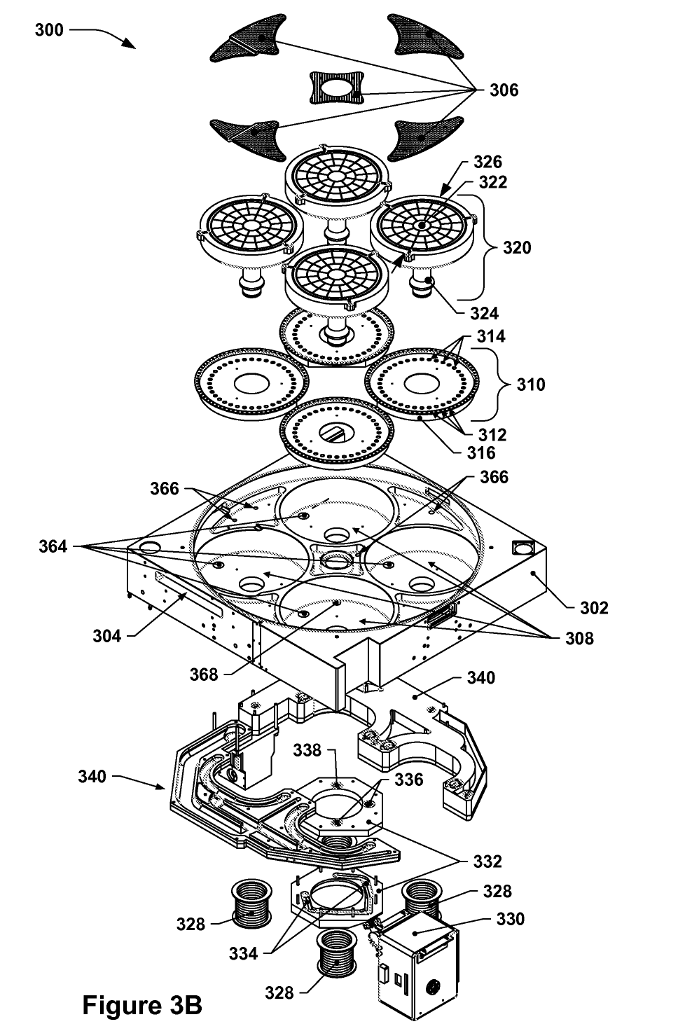

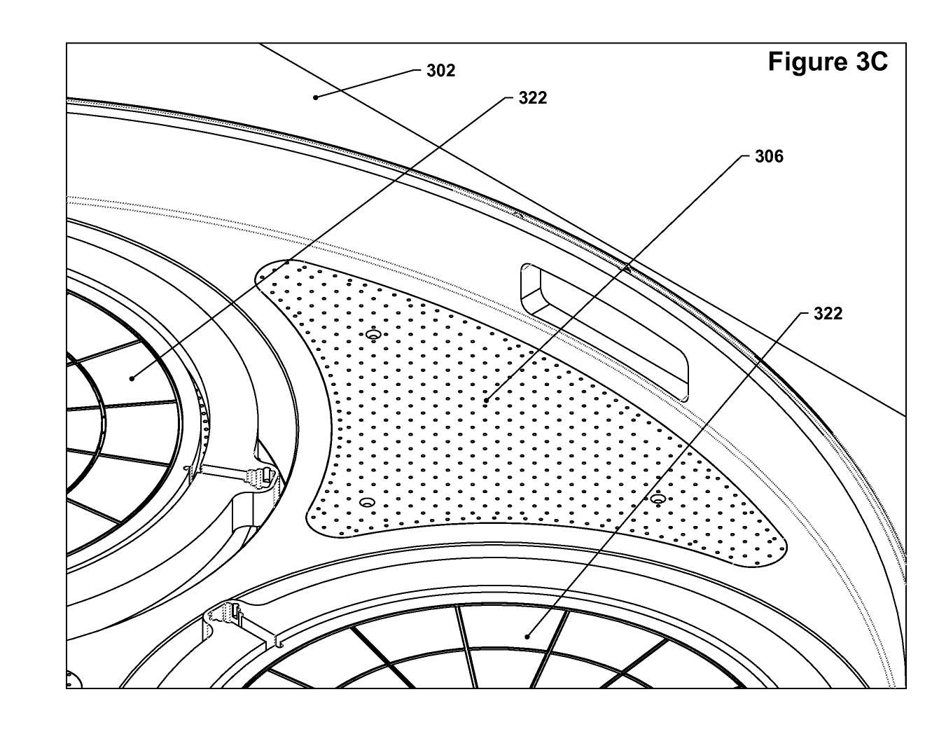

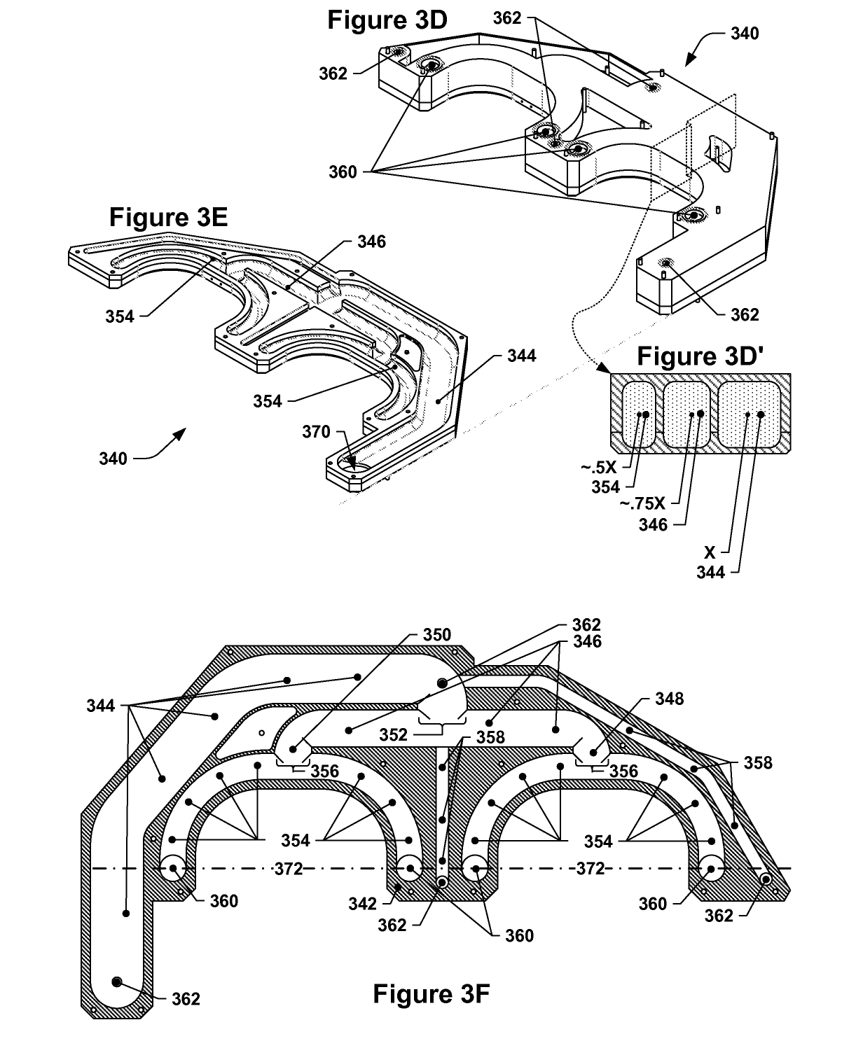

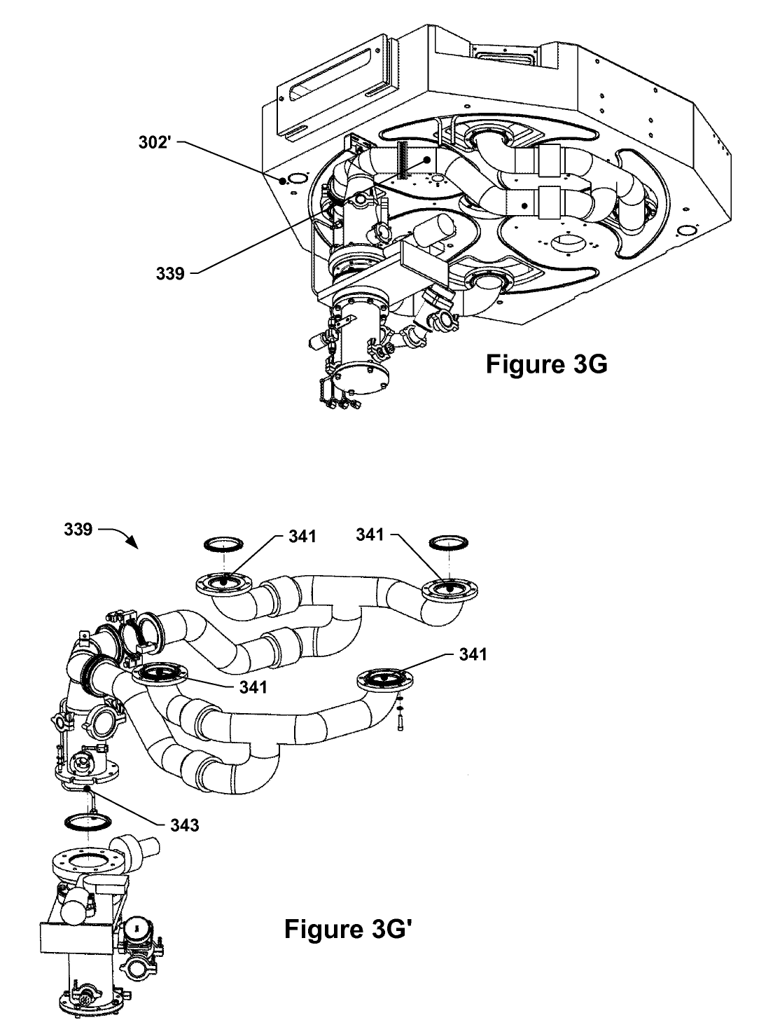

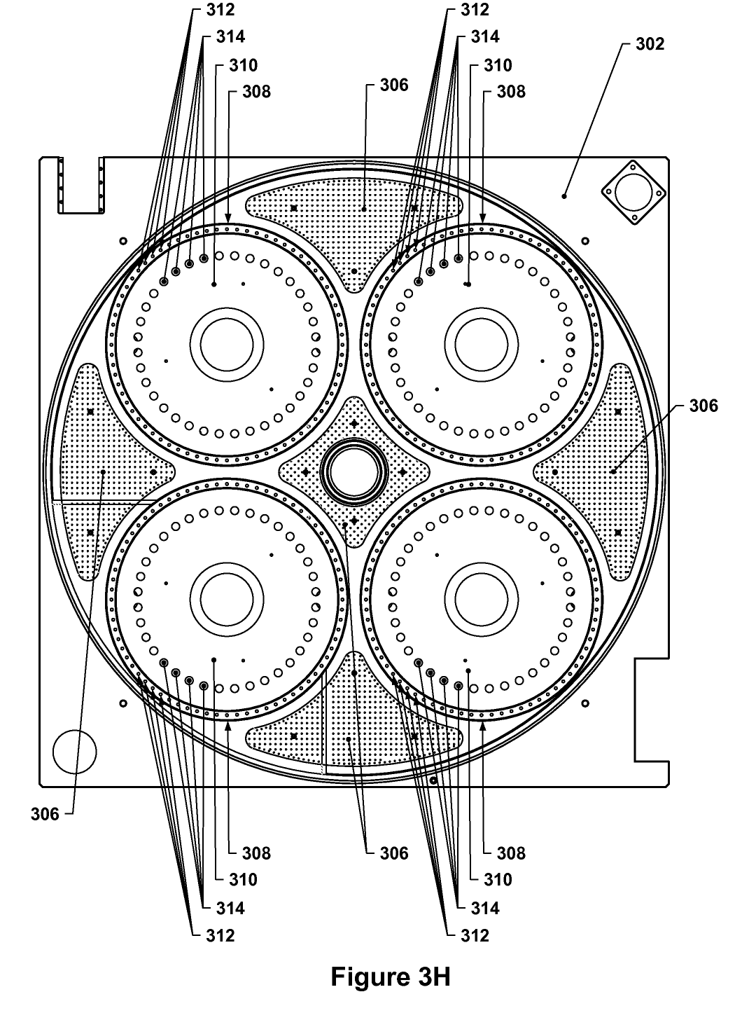

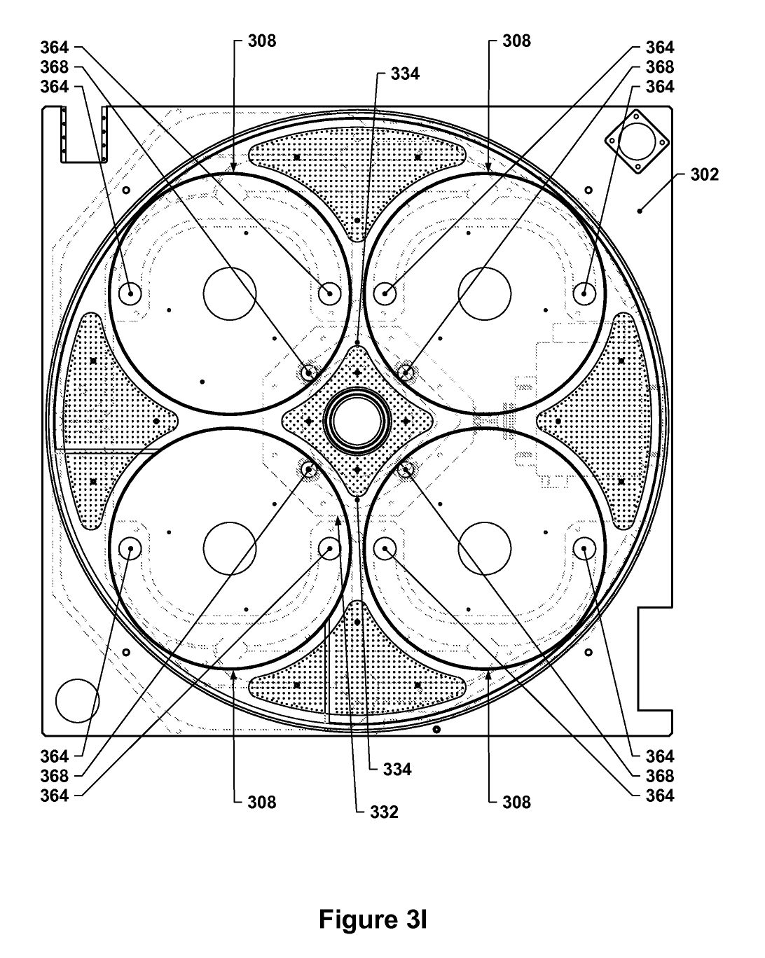

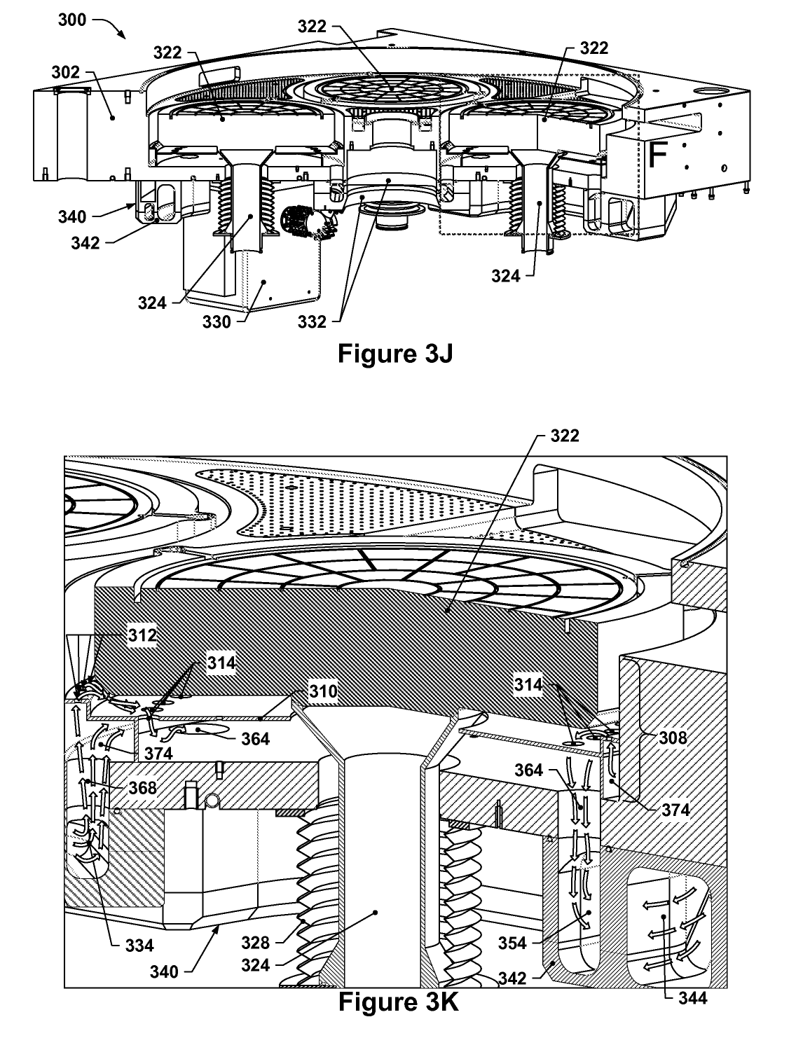

This concept is discussed in further detail below with reference to FIGS. 3A through 3K. FIG. 3A depicts an isometric view of a portion of an example of a multi-station semiconductor processing tool. The multi-station semiconductor processing tool 300 may include a plurality of stations housed within a chamber housing 302. Each station may have a pedestal 322. In some implementations, interstitial baffles 306 may be used to provide for flow of a gas curtain in the interstices between the stations. The gas curtain may help prevent the process gases from a particular station from flowing into the other process stations or from contacting the walls of the chamber housing 302. The multi-station semiconductor processing tool 300 may have a cover (not shown) that may seal the chamber housing 302. The cover may include, or may have features that accommodate, showerheads (not shown) for distributing process gases across the pedestals 322 and the semiconductor wafers (not shown) that may be placed thereupon. The chamber housing 302 may have one or more wafer load/unload ports 304 to allow semiconductor wafers to be inserted into or removed from the chamber housing 302. A remote plasma source 330 may be connected with the chamber housing 302 to provide auxiliary cleaning gas. One or more vacuum foreline manifolds 340 may be connected with the underside of the chamber housing 302.

FIG. 3B depicts an isometric exploded view of the example multi-station semiconductor processing tool of FIG. 3A. As can be seen, the pedestal 322 may be part of a larger pedestal assembly 320 that may include a pedestal support column 324. The pedestal 322 may have a nominal diameter 326. Bellows 328, shown separately from the pedestal assembly 320, may also be included in the pedestal assembly 320.

Also visible in FIG. 3B are pedestal well baffles 310, which may be substantially axially or radially symmetric (although there may be some departures from such symmetry). The pedestal well baffles 310 may include a plurality of vacuum ports 314 arranged in a substantially circular pattern, as well as a plurality of auxiliary gas cleaning ports 312, also arranged in a substantially circular pattern. The pedestal well baffles 310 may be located in the bottom of pedestal wells 308 in the chamber housing 302 and may be located beneath the pedestals 322. Partition walls 316 on the pedestal well baffles 310 may offset the pedestal well baffles 310 from the bottom of the pedestal wells 308 and may also serve to separate a cleaning gas plenum volume (not specifically indicated) that is in fluid communication with the auxiliary cleaning gas ports 312 from a vacuum plenum volume (also not specifically indicated) that is in fluid communication with the vacuum ports 314. While it may be advantageous to ensure that the partition walls 316 hermetically seal the cleaning gas plenum volume from the vacuum plenum volume, some leakage between the two plenum volumes may be tolerated (although such leakage will reduce the amount of auxiliary cleaning gas that may reach the underside of the pedestal 322).

The cleaning gas plenum volumes may also be fluidly connected with housing cleaning ports 368 located in the bottoms of the pedestal wells 308. In the depicted implementation, only one housing cleaning port 368 is visible, although each pedestal well 308 shown includes a housing cleaning port 368 for each of the pedestal wells 308.

Similarly, the vacuum plenum volumes may be fluidly connected with housing vacuum ports 364 that are located in the bottoms of the pedestal wells 308.

Also visible are housing interstitial vacuum ports 366, which may be used to draw a vacuum through the interstitial baffles 306.

The housing vacuum ports 364 and the interstitial vacuum ports 366 may be fluidly connected with the vacuum foreline manifolds 340. In the implementation shown, there are two vacuum foreline manifolds 340 that are largely mirror images of one another, although other implementations may feature one vacuum foreline manifold 340 or more than two vacuum foreline manifolds 340. In some implementations, multiple vacuum foreline manifolds 340 may not be mirror images of one another.

Similarly, the housing cleaning ports 368 may be fluidly connected with a cleaning gas manifold 332. In the implementation shown, the cleaning gas manifold 332 may have four cleaning gas supply ports, one for each pedestal well 308. Each cleaning gas supply port may be provided auxiliary cleaning gas via a cleaning gas supply passage 334, which may, in turn, be provided with auxiliary cleaning gas by a remote plasma source 330 (or by another source). High-flow cleaning gas ports 336 may provide a larger amount of auxiliary cleaning gas to the two process stations closer to the remote plasma source 330 than low-flow cleaning gas ports 338 may provide to the two process stations further from the remote plasma source 330. This behavior is caused by virtue of the sequential spacing of each pair of the high/low flow cleaning gas ports 336/338 on the cleaning gas supply passage. As a result, the flow path length to the high-flow cleaning gas ports 336 is less than the flow path length to the low-flow cleaning gas ports 338. This causes the flow conductance to the high-flow cleaning gas ports 336 to be higher than the flow conductance to the low-flow cleaning gas ports 338, resulting in increased flow through the high-flow cleaning gas ports 336 as compared with the low-flow cleaning gas ports 338. The resulting biased supply of auxiliary cleaning gas to the process stations may be used when the accumulation rates of deposition material on the underside of the pedestals varies from process station to process station. In the depicted implementation, the accumulation rate on the underside of the pedestals 322 in the two process stations closest to the remote plasma source 330 is greater than that in the remaining two process stations. Accordingly, the biased flow of auxiliary cleaning gas may allow the cleaning operations performed on the undersides of all four pedestals 322 to be performed simultaneously while reducing the potential for overetching (damaging) the pedestals 322 or other components in the process stations furthest from the remote plasma source 330.

It is to be understood that in implementations where the process stations experience similar degrees of accumulated deposition material on the underside of the pedestals 322, the cleaning gas supply passage 334 may be modified so as to provide substantially equal flow conductance to each cleaning gas supply port (thus producing substantially unbiased auxiliary cleaning gas flow).

FIG. 3C depicts an isometric detail view of a portion of the example multi-station semiconductor processing tool of FIG. 3A contained within the dotted rectangle. As can be seen, the interstitial baffle 306 substantially fills one of the interstices between the process stations.

FIG. 3D depicts an isometric view of an example vacuum foreline manifold included in the example multi-station semiconductor processing tool of FIG. 3A. FIG. 3D′ depicts a removed broken section view of a portion of the example vacuum foreline manifold of FIG. 3D. FIG. 3E depicts an isometric top section view of the example vacuum foreline manifold shown in FIG. 3D. FIG. 3F depicts a bottom section view of the example vacuum foreline manifold shown in FIG. 3D.

A foreline is used herein to refer to the portion (or a portion) of a vacuum system that connects the system from which gas is being evacuated to the vacuum pump or vacuum source. Traditionally, vacuum forelines used in semiconductor manufacturing applications are typically provided using pieces of stainless steel tubing (SST) or “line” (thus the moniker “foreline”) joined together using various threaded or flanged fittings, e.g., International Standards Organization (ISO) NW fittings. Forelines for complex systems that connect multiple vacuum ports to a vacuum source may be quite complicated and may require multiple T-intersections, fittings, and complex, three-dimensional tubing bends. For a multi-station semiconductor processing tool such as that shown in FIG. 3A, such a foreline assembly might require more than 12 different connections and at least 7 separate pieces of SST. The vacuum ports for a multi-station semiconductor processing tool are typically connected to a single vacuum pump or source via the foreline(s).

The vacuum foreline manifold 340 differs from traditional forelines in that the vacuum foreline manifold 340 presents an integrated, substantially flat manifold body 342 that may be used to provide substantially equal path lengths from a feed vacuum port 370 in the manifold body to each of several manifold vacuum ports 360. Such an equal-path length arrangement of flow paths results in physical path length symmetry within the vacuum foreline manifold 340 that may produce substantially uniform pumping pressures and flows at each of the manifold vacuum ports 360. It may also be possible to also achieve substantially uniform pumping pressures and flows at the manifold vacuum ports 360 with unequal-length flow paths, but such solutions typically rely on using differently-sized orifices at various locations and are typically only effective at one pressure/flow regime—the equal-length flow paths shown in the manifold body 342 produce substantially uniform pumping pressures and flows at the manifold vacuum ports 360 over a large range of pressures and flow regimes.

The manifold body 342 may be formed out of a substantially monolithic piece of material, e.g., a milled billet of aluminum or a machined aluminum casting. The manifold body 342 may have a number of passages or channels located within, including U-shaped passages 354, a bridging passage or passages 346, and a feed passage 344. The two ends of the U-shaped passages 354 may each terminate at one of the manifold vacuum ports 360, and the manifold vacuum ports 360 of the vacuum foreline manifold 340 may lie along a common axis 372. In some implementations, however, the manifold vacuum ports 360 of a vacuum foreline manifold 340 may not lie along a common axis 372.

The bridging passage 346 may have a first end 348 and a second end 350 that fluidly connect the bridging passage 346 to the U-shaped passage midpoints 356, respectively, and the feed passage 344 may fluidly connect the feed vacuum port 370 to the bridging passage midpoint 352. Thus, the centerline path length from the feed vacuum port 370 to each of the four manifold vacuum ports 360 shown is substantially the same. This allows the vacuum drawn on each pair of manifold vacuum ports 360 of each U-shaped passage 354 (and thus the housing vacuum ports 364 to which they are respectively interfaced) to be substantially symmetric. This promotes symmetric vacuum flow through the vacuum ports 314 in the pedestal well baffle 310. Such symmetric vacuum flow may be beneficial in maintaining uniform deposition gas flow across the pedestal 322 (and semiconductor wafer) during deposition operations.

In addition to the passages leading to the manifold vacuum ports 360, the manifold body 342 may also include one or more interstitial vacuum passages 358 that may lead to manifold interstitial vacuum ports 362. Some manifold interstitial vacuum ports 362 may directly connect with the feed passage 344 without an intervening interstitial vacuum passage 358. The manifold interstitial vacuum ports 362 may lead to plenums associated with the interstitial baffles 306, allowing a vacuum to be drawn through the interstitial baffles 306. As shown, the manifold interstitial vacuum ports 362 are all connected with the feed passage 344 at a point “upstream,” i.e., closer to the vacuum source or vacuum pump, of the bridging passage 346, i.e., at a point before the flow from the feed passage 344 first splits in order to be directed to the manifold vacuum ports 360.

The various passages in the manifold body 342 may be capped by a lid that is mated to the manifold body; the lid may have matching passages and may be brazed onto the manifold body 342 to provide a maintenance-free, durable, vacuum-tight seal that is unsusceptible to damage that might harm other seals, e.g., elastomeric seals. Elastomeric or other non-permanent seals may be used to seal the interfaces between the manifold vacuum ports 360 and the housing vacuum ports 364 and between the manifold interstitial vacuum ports 362 and the housing interstitial vacuum ports 366.

In some implementations, some or all of the passages in the manifold body 342 described above may be machined or otherwise formed directly in the chamber housing 302. However, such an implementation may prove to be practically difficult to implement in some scenarios due to the size of the chamber housing. For example, it may be difficult to find a provider of semiconductor-grade brazing services that is capable of handling a 4-station chamber housing 302 for brazing a cap directly to the chamber housing 302 to seal passages provided directly in the chamber housing 302 (in the pictured example, the chamber housing 302 is approximately 5′ square by 1′ deep). Of course, if such capability becomes commercially available, the layout and routing of the passages in the manifold body 342 may be implemented in the chamber housing itself, obviating the need for separate manifold bodies 342. In such implementations, the chamber housing 302 may, in effect, become the manifold body 342.

As can be seen, each vacuum foreline manifold 340 presents a relatively compact module that packages the vacuum forelines leading to the feed vacuum port 370 within a volume that is slightly deeper in the vertical (thickness) direction, i.e., in a direction that is substantially normal to the wafer-supporting surface of the pedestals 322, than the largest diameter or dimension in that same direction of the passages within the manifold body 342. For example, the nominal maximum depth of the vacuum foreline manifold 340 (exclusive of fasteners) as shown in FIG. 3D may be approximately 5.125″, whereas the height in the same direction of the feed passage 344 may be approximately 4.25″. Expressed in relative terms, such an example vacuum foreline manifold may have a nominal thickness in the vertical direction that is approximately 20% greater than the height of the largest-height passage (in the vertical direction) in the vacuum foreline manifold. In other implementations, the nominal thickness of the vacuum foreline manifold in the vertical direction may be between 10% and 30%, 5% and 40%, or between 5% and 50% of the largest-height (in the vertical direction) passage in the vacuum foreline manifold.

Moreover, due to the compact, “flat” packaging of the vacuum foreline manifold 340, the vacuum foreline manifold 340 may be placed flat against the chamber housing 302, resulting in good thermal contact between the vacuum foreline manifold 340 and the chamber housing 302. This allows the vacuum foreline manifold 340 to be heated using heat from the chamber housing 302. In some semiconductor processing operations, the chamber housing 302 may be heated to prevent or reduce deposition on the interior surfaces of the chamber housing 302. Vacuum forelines may also be heated in such processes to similarly prevent or reduce deposition within the vacuum forelines themselves. Typically, due to the fact that the vacuum foreline tubing that is typically used only contacts the chamber housing at the housing vacuum ports 364 (or the equivalent), the amount of heat that is provided to such vacuum forelines is considerably less than that may be provided to the manifold body 342 due to the much larger contact patch between the manifold body 342 and the chamber housing 302.

Each passage in the vacuum foreline manifold may decrease in size with respect to the closest adjacent upstream, i.e., closer to the vacuum pump or vacuum source, passage. For example, the feed passage 344 may have a cross-sectional flow area of X, the bridging passage 346 may have a cross-sectional flow area of approximately 0.75X, and the U-shaped passages 354 may have cross-sectional flow areas of approximately 0.5X. In FIG. 3D, a break-out section is shown (FIG. 3D′) illustrating the decreasing cross-sectional flow areas of these three passages. As can be seen, the passages may be formed to have rectangular cross-sections with rounded corners, although other cross-sectional shapes are also contemplated, e.g., circular, oval, etc. In the particular implementation shown, the feed passage 344, the bridging passage 346, and the U-shaped passages 354 all have substantially the same height in the vertical direction. Accordingly, the widths of these passages may follow the same general progression as the cross-sectional areas. For example, the feed passage 344 may have a width of Y, the bridging passage 346 may have a width of approximately 0.75Y, and the U-shaped passages 354 may have widths of approximately 0.5Y. It is to be understood that these values are approximate, e.g., the U-shaped passages 354 as shown have widths that are approximately 0.53Y rather than exactly 0.5Y. It is to be further understood that other configurations may have different relative size ratios between the different passages, e.g., when a different number of manifold vacuum ports 360 are provided by the vacuum foreline manifold 340.

The vacuum foreline manifold 340 pictured in FIGS. 3D through 3F includes manifold vacuum ports 360 that have nominal diameters of approximately 2″, and a feed vacuum port 370 that is approximately twice as large in diameter. The various manifold interstitial vacuum ports 362 that are shown may have diameters of approximately 0.75″ to 1″. To give some further sense of scale, the centers of the manifold vacuum ports 360 located at the ends of one of the two U-shaped passages 354 are located approximately 19″ apart and the U-shaped passage midpoints 356 are located approximately 24″ apart (center-to-center).

As can be seen, due to the generally monolithic nature of the vacuum foreline manifold 340, a substantial region on the underside of the chamber housing 302 around the center of each process station is clear of vacuum-related hardware, e.g., the particular implementation shown has a circular regions on the underside of the chamber housing 302 that are approximately 12.75″ in diameter about the center of each process station that are clear of vacuum-related hardware. This allows for increased accommodation of other hardware that may be necessary for operation of the multi-station semiconductor processing tool, e.g., lift motors/actuators for raising and lowering the pedestal assemblies 320, cooling or heating systems for heating the chamber housing 302, the remote plasma source 330 and the cleaning gas manifold 332 (although these components are also located so as to be outside of the circular region), electrode connections, etc.

Another benefit of the integrated vacuum foreline manifold shown over traditional or conventional vacuum forelines featuring individual tube segments joined together using standard ISO/NW fittings is that the number of disconnectable seals is drastically reduced. For example, for each vacuum foreline manifold 340, there are only 9 sealed, disconnectable interfaces—the four manifold vacuum ports 360, four manifold interstitial vacuum ports 362, and the feed vacuum port 370. By contrast, replicating a similar flow path arrangement using traditional tube/fitting hardware might require as many as 20 sealed, disconnectable interfaces.

Furthermore, due to the thermal damping effect of the integrated vacuum foreline manifold, the seals used to seal the manifold vacuum ports to the chamber housing vacuum ports may experience substantially isothermal environments (or at least thermal environments with less variability) as compared with seals used in conventional vacuum forelines featuring individual tube segments joined together using standard ISO/NW fittings, at least with respect to normal continuous processing operations. This may promote seal life, e.g., elastomeric seals may require less frequent replacement due to thermal cycling issues when used with an integrated vacuum foreline manifold as compared with a conventional vacuum foreline.

FIGS. 3G and 3G′ depict a bottom isometric view of a multi-station semiconductor processing tool (a 300 mm ALTUS multi-station semiconductor processing tool produced by Novellus Systems, Inc. (now Lam Research Corp.) having a traditional vacuum foreline and an exploded view of the traditional vacuum foreline, respectively. FIGS. 3G and 3G′ are provided to illustrate the various bends and tubing routing often required in conventional vacuum forelines for multi-station semiconductor processing chambers that are largely eliminated when using the vacuum foreline manifold discussed herein, for example, with respect to FIGS. 3

As can be seen, a considerable number of bends, brazed connections, disconnectable flange connections, and tube sections are required for the depicted conventional vacuum foreline 339 that is connected with chamber housing 302′ in FIG. 3G. Moreover, the depicted conventional vacuum foreline, as is evident in FIG. 3G′, only provides for four points of connection to the chamber housing 302′. Were the conventional vacuum foreline 302′ to be expanded to connect to a chamber housing similar to the chamber housing 302 of FIGS. 3A and 3B, i.e., a chamber housing with sixteen vacuum ports and interstitial vacuum ports, the conventional vacuum foreline shown would present an even more convoluted and complex shape. It is quite evident that the vacuum foreline manifold 340, with its compact volume and integrated nature, presents a superior vacuum foreline alternative to the conventional vacuum foreline shown in FIGS. 3G and 3G′. Furthermore, if it is necessary to heat the vacuum forelines, the conventional vacuum forelines shown may require a heating jacket (and control loop) for each tube section in the vacuum foreline, adding to the overall system cost, complexity, and bulk. The present inventors have realized that the conventional vacuum foreline is largely incapable of benefiting from any heat provided to the chamber housing 302′ since the conventional vacuum foreline tubes are separated from the chamber housing 302′ except at the locations where the conventional vacuum foreline is connected with the chamber housing 302′. By contrast, the integrated vacuum foreline manifold 340 discussed herein, as discussed above, may be in thermally conductive contact with the chamber housing 302 across a large portion of one side. Additionally, due to the increased amount of material in the integrated vacuum foreline manifold 340 due to its substantially monolithic construction, there is an increased amount of material to help dampen out variations in heating and to distribute heat in a more even manner to the various internal passages.

FIG. 3H depicts a top view of the example multi-station semiconductor processing tool of FIG. 3A with some components removed. FIG. 3I depicts a top view of the example multi-station semiconductor processing tool of FIG. 3A with some additional components removed. FIGS. 3H and 3I are to-scale with one another.

FIGS. 3H and 3I further illustrate the substantially circular arrangement of vacuum ports 314 and the auxiliary cleaning gas ports 312 in the pedestal well baffle 310. Also shown in FIG. 3I in dashed gray lines is the remote plasma source 330, the cleaning gas manifold 332, and the cleaning gas supply passage 334. The two vacuum foreline manifolds 340 are also shown in dashed gray lines.

FIG. 3J depicts an off-angle cutaway view of the example multi-station semiconductor processing tool of FIG. 3A. Various structures of the multi-station semiconductor processing tool 300 are visible, including three of four pedestals 322, the chamber housing 302, pedestal support columns 324, the remote plasma source 330, the cleaning gas manifold 332, and the vacuum foreline manifold 340 and the manifold body 342.

FIG. 3K depicts a detail view of the portion of the example multi-station semiconductor processing tool of FIG. 3J contained within the dotted rectangle. As can be seen, auxiliary cleaning gas (white arrows) may flow from the cleaning gas supply passage 334, through the housing cleaning port 368, and into the cleaning gas plenum 374. From the cleaning gas plenum 374, the auxiliary cleaning gas may flow through the substantially circular pattern of auxiliary cleaning gas ports 312 and may then flow radially inwards towards the vacuum ports 312. From the vacuum ports 312, the auxiliary cleaning gas may be drawn into the vacuum plenum and then into the housing vacuum ports 364 and the U-shaped passage 354. After flowing through the U-shaped passage 354 and the bridging passage (not shown) of the manifold body 342, the auxiliary cleaning gas may then flow towards the feed vacuum port (not shown) via the feed passage 344.

While not shown, cleaning gas may also be flowed from a showerhead or similar structure towards the top of the pedestal 322. This cleaning gas may then flow down the sides of the pedestal 322 and into the vacuum ports 314.

The specific multi-station semiconductor processing tool of FIGS. 3A through 3K may be used, for example, to provide deposition of Tungsten (W) on semiconductor wafers, e.g., via a W chemical vapor deposition (CVD) operation. In W deposition, each successive deposition operation may cause a thin layer of W to be deposited on non-semiconductor wafer surfaces, e.g., on the pedestal and on chamber surfaces. Such deposition material accumulation may, over successive deposition cycles, result in accumulated deposition material thicknesses on the order of tens of microns, e.g., 50 microns. Much of the accumulated W material may be located on the underside of the pedestal (as compared with the top of the pedestal) due to the top of the pedestal being shielded by the semiconductor wafer during most deposition operations. The accumulated W material on the underside of the pedestal may be removed by providing NF₃ as a cleaning gas via the auxiliary cleaning gas ports. The implementation shown in FIGS. 3A through 3K may exhibit cleaning speeds that are nearly twice as fast as may be possible using only the showerhead to provide cleaning gases, i.e., without the use of an auxiliary cleaning gas.

The materials used for the various components herein may generally be selected from materials commonly used for semiconductor processing equipment, e.g., alloys or materials that are chemically compatible with the process environments used and that exhibit desired thermal, strength, and electrical properties. For example, the vacuum foreline manifold, the chamber housing, and the cleaning gas manifold may be made from aluminum and may be coated or otherwise treated, if necessary, to provide resistance to semiconductor processing environments. Other materials may be used as well. For example, the pedestal may be made from aluminum or a ceramic material. The showerhead may be made from aluminum, ceramic material, stainless steel, or other material.

It is to be understood that the pedestal-underside cleaning techniques, and apparatus suitable for performing such techniques, may be implemented in the context of either a single-station semiconductor processing chamber or a multi-station semiconductor processing chamber (or tool). It is also to be understood that while the integrated vacuum foreline manifold discussed above may be implemented in the context of a single-station semiconductor processing chamber, such integrated vacuum foreline manifolds realize their maximum potential when used in the context of multi-station semiconductor processing chambers or tools.

The equipment described herein may be connected with various other pieces of equipment, such as gas supply sources/lines, flow controllers, valves, power supplies, RF generators, sensors such as pressure, temperature, or flow rate measurement devices, and so forth. Such chambers or tools may also include a system controller having instructions for controlling the various valves, flow controllers, and other equipment to provide a desired semiconductor process using the chamber, pedestals, showerheads, vacuum systems, and cleaning systems discussed herein. The instructions may include, for example, instructions to control the semiconductor processing tool in accordance with the technique discussed with respect to FIG. 2. The system controller may typically include one or more memory devices and one or more processors configured to execute the instructions so that the apparatus will perform a method in accordance with the present disclosure. Machine-readable media containing instructions for controlling process operations in accordance with the present disclosure may be coupled to the system controller.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

It will also be understood that unless features in any of the particular described implementations are expressly identified as incompatible with one another or the surrounding context implies that they are mutually exclusive and not readily combinable in a complementary and/or supportive sense, the totality of this disclosure contemplates and envisions that specific features of those complementary implementations can be selectively combined to provide one or more comprehensive, but slightly different, technical solutions. It will therefore be further appreciated that the above description has been given by way of example only and that modifications in detail may be made within the scope of the disclosure.

1. A method of cleaning a semiconductor processing chamber containing a showerhead, a pedestal with a wafer support side facing the showerhead and an underside opposite the wafer support side, and one or more auxiliary cleaning gas ports configured to flow cleaning gas towards the underside of the showerhead, the method comprising:
flowing a first cleaning gas from the showerhead towards the wafer support side of the pedestal; and
flowing a second cleaning gas from the one or more auxiliary cleaning gas ports towards the underside of the pedestal.

2. The method of claim 1, wherein the first cleaning gas and the second cleaning gas are the same gas.

3. The method of claim 1, wherein the second cleaning gas is activated fluorine.

4. The method of claim 1, wherein the first cleaning gas and the second cleaning gas are flowed for substantially coextensive periods of time.

5. The method of claim 1, wherein the one or more auxiliary cleaning gas ports includes a plurality of auxiliary cleaning gas ports arranged in a substantially circular pattern centered on the pedestal.

6. The method of claim 5, wherein the semiconductor processing chamber further includes a plurality of vacuum ports arranged in a substantially circular pattern centered on the pedestal and located within the substantially circular pattern that the plurality of auxiliary cleaning gas ports is in, the method further comprising:
drawing a vacuum through the vacuum ports to cause the second cleaning gas to flow into the vacuum ports.

7. The method of claim 6, wherein the pedestal has a nominal outer diameter and the substantially circular pattern of vacuum ports has a diameter less than the nominal outer diameter and the substantially circular pattern that the plurality of auxiliary cleaning gas ports are in has a diameter greater than the nominal outer diameter.

8. The method of claim 1, further comprising:
flowing deposition gas from the showerhead towards the wafer support side of the pedestal; and
drawing a vacuum through the vacuum ports to cause the deposition gas to flow into the vacuum ports.

9. The method of claim 8, further comprising:
accumulating a deposition layer on the support side of the pedestal and on the underside of the pedestal, wherein:
the deposition layer has a first average thickness on the support side of the pedestal,
the deposition layer has a second average thickness on the underside of the pedestal, and
the second average thickness is greater than the first average thickness.

10. The method of claim 8, wherein the deposition gas is a tungsten deposition gas.

11. The method of claim 9, wherein:
the first cleaning gas removes the deposition layer on the support side of the pedestal with a greater efficiency than the first cleaning gas removes the deposition layer on the underside of the pedestal, and
the second cleaning gas removes the deposition layer on the underside of the pedestal with a greater efficiency than the second cleaning gas removes the deposition layer on the support side of the pedestal.

12. A semiconductor processing chamber comprising:
a chamber housing;
a pedestal having a wafer support side and an underside opposite the wafer support side, the pedestal located within the chamber housing; and
a plurality of auxiliary cleaning gas ports located within the chamber housing and such that the underside of the pedestal is between the wafer support side of the pedestal and the plurality of auxiliary cleaning gas ports, the auxiliary cleaning gas ports oriented to flow an auxiliary gas onto the underside of the pedestal.

13. The semiconductor processing chamber of claim 12, further comprising:
a showerhead, the showerhead located such that the wafer support side of the pedestal is between the underside of the pedestal and the showerhead, wherein the showerhead is configured to flow deposition gas onto the pedestal.

14. The semiconductor processing chamber of claim 13, wherein the showerhead is further configured to flow a cleaning gas onto the showerhead.

15. The semiconductor processing chamber of claim 12, further comprising:
a plurality of vacuum ports located within the chamber housing and such that the underside of the pedestal is between the wafer support side of the pedestal and the plurality of vacuum ports.

16. The semiconductor processing chamber of claim 15, wherein the auxiliary cleaning gas ports of the plurality of auxiliary cleaning gas ports are arranged in a substantially circular pattern about a center axis of the pedestal, and the vacuum ports of the plurality of vacuum ports are arranged in a substantially circular pattern about the center axis of the pedestal.

17. The semiconductor processing chamber of claim 16, wherein the substantially circular pattern of auxiliary cleaning gas ports has a larger nominal pattern diameter than the substantially circular pattern of vacuum ports.

18. A vacuum foreline manifold comprising:
a manifold body;
two U-shaped passages within the manifold body, wherein:
each U-shaped passage has two manifold vacuum ports passing out of the manifold body, and
each of the two manifold vacuum ports is located at a different end of the U-shaped passage;
a bridging passage within the manifold body, wherein:
the bridging passage has a first end and a second end,
the first end of the bridging passage is fluidly connected with one of the U-shaped passages at the U-shaped passage's midpoint, and
the second end of the bridging passage is fluidly connected with the other U-shaped passage at the other U-shaped passage's midpoint; and
a feed passage, wherein:
the feed passage is fluidly connected to the bridging passage at the bridging passage's midpoint, and
the feed passage, the bridging passage, and the U-shaped passages all follow two-dimensional paths in the same plane or parallel planes.

19. (canceled)

20. The vacuum foreline manifold of claim 18, wherein:
the feed passage has a cross-sectional flow area Y,
the bridging passage has a cross-sectional flow area of approximately 0.75Y, and the U-shaped passages both have a cross-sectional flow area of approximately 0.5Y.

21. (canceled)

22. The vacuum foreline manifold of claim 18, wherein:
the manifold body has a height in a direction perpendicular to the plane or planes of the two-dimensional paths that is between about 10% and 30% greater than a maximum height in a direction perpendicular to the plane or planes of the two-dimensional paths of the feed passage, the bridging passage, and the U-shaped passages.

23. (canceled)

24. (canceled)
